(19) United States
(12) Patent Application Publication
(10) Pub. No.: US 2015/0030984 A1
(43) Pub. Date: Jan. 29, 2015

(54) METHOD OF MANUFACTURING A FLEXOGRAPHIC PRINTING PLATE FOR HIGH-RESOLUTION PRINTING

(71) Applicant: Ed S. Ramakrishnan, Spring, TX (US)

(72) Inventor: Ed S. Ramakrishnan, Spring, TX (US)

(73) Assignee: UNI-PIXEL DISPLAYS, INC., The Woodlands, TX (US)

(21) Appl. No.: 13/952,228

(22) Filed: Jul. 26, 2013

(51) Int. Cl. G03F 7/20; B41C 1/055

(52) U.S. Cl. CPC G03F 7/2022; B41C 1/055
USPC 430/306

(57) ABSTRACT

A method of manufacturing a flexographic printing plate includes exposing a bottom side of a flexographic printing plate substrate to UV-A radiation for a first exposure time. A top side of the flexographic printing plate substrate is exposed to UV-A radiation through a thermal imaging layer. The bottom side of the flexographic printing plate substrate is exposed to UV-A radiation for a second exposure time. The flexographic printing plate substrate is developed. The flexographic printing plate is cured. A sum of the first and second exposure times set a relief depth.

### BACKGROUND OF THE INVENTION

An electronic device with a touch screen allows a user to control the device by touch. The user may interact directly with the objects depicted on a display by touch or gestures. Touch screens are commonly found in consumer, commercial, and industrial devices including smartphones, tablets, laptop computers, desktop computers, monitors, portable gaming devices, gaming consoles, and televisions.

A touch screen includes a touch sensor that includes a pattern of conductive lines disposed on a substrate. Flexographic printing is a rotary relief printing process that transfers an image to a substrate. A flexographic printing process may be adapted for use in the manufacture of touch sensors.

### BRIEF SUMMARY OF THE INVENTION

According to one aspect of one or more embodiments of the present invention, a method of manufacturing a flexographic printing plate includes exposing a bottom side of a flexographic printing plate substrate to UV-A radiation for a first exposure time. A top side of the flexographic printing plate substrate is exposed to UV-A radiation through a thermal imaging layer. The bottom side of the flexographic printing plate substrate is exposed to UV-A radiation for a second exposure time. The flexographic printing plate substrate is developed. The flexographic printing plate is cured. A sum of the first and second exposure times set a relief depth.

Other aspects of the present invention will be apparent from the following description and claims.

### BRIEF DESCRIPTION OF THE DRAWINGS

FIG. 1 shows a portion of a conductive pattern design on a flexible and transparent substrate in accordance with one or more embodiments of the present invention.

FIG. 2 shows a flexographic printing system in accordance with one or more embodiments of the present invention.

FIG. 3 shows a method of manufacturing a conventional flexographic printing plate.

FIG. 4 shows a flexographic printing plate substrate at early stages of manufacture in accordance with one or more embodiments of the present invention.

FIG. 5 shows a multi-step exposure of the flexographic printing plate substrate in accordance with one or more embodiments of the present invention.

FIG. 6 shows post-exposure processing of the flexographic printing plate substrate in accordance with one or more embodiments of the present invention.

FIG. 7 shows a method of manufacturing a high-resolution flexographic printing plate in accordance with one or more embodiments of the present invention.

### DETAILED DESCRIPTION OF THE INVENTION

One or more embodiments of the present invention are described in detail with reference to the accompanying figures. For consistency, like elements in the various figures are denoted by like reference numerals. In the following detailed description of the present invention, specific details are set forth in order to provide a thorough understanding of the present invention. In other instances, well-known features to one of ordinary skill in the art are not described to avoid obscuring the description of the present invention.

A conventional flexographic printing system uses a flexographic printing plate, sometimes referred to as a flexomaster, to transfer an image to a substrate. The flexographic printing plate includes one or more embossing patterns, or raised projections, that have distal ends onto which ink or other material may be deposited. In operation, the inked flexographic printing plate transfers an ink image of the one or more embossing patterns to the substrate. The ability of a conventional flexographic printing system to print high resolution lines or features is limited by the stability of features formed on the flexographic printing plate.

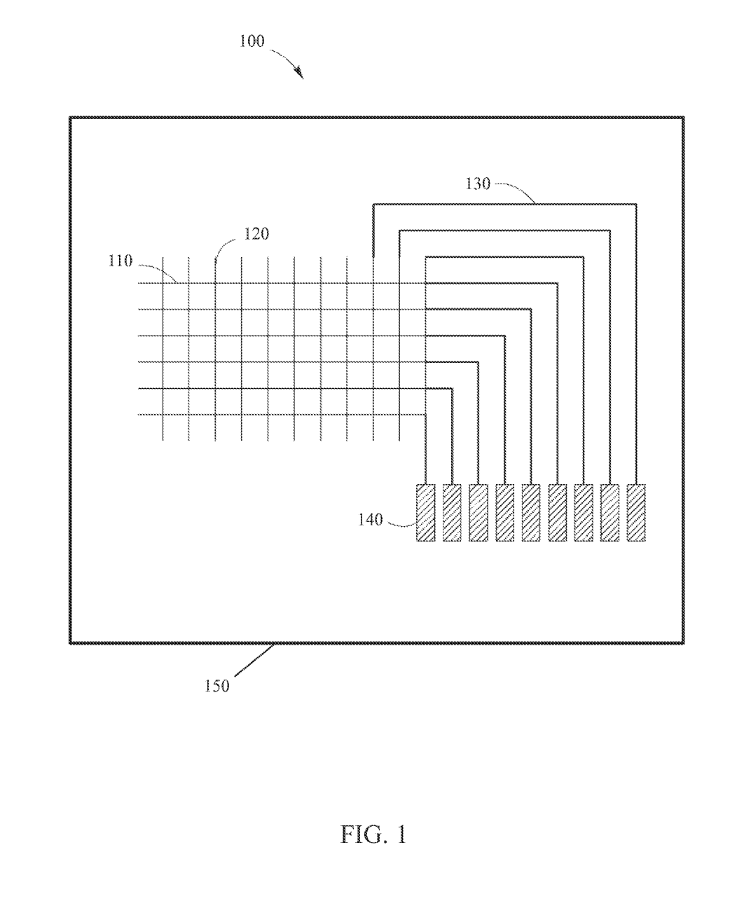

FIG. 1 shows a portion of a conductive pattern design 100 on a flexible and transparent substrate 150 in accordance with one or more embodiments of the present invention. Two or more conductive pattern designs 100 may be used to form a projected capacitance touch sensor (not independently illustrated). In certain embodiments, conductive pattern design 100 may include a micro mesh formed by a plurality of parallel x-axis conductive lines 110 and a plurality of parallel y-axis conductive lines 120 disposed on substrate 150. The x-axis conductive lines 110 may be perpendicular or angled relative to the y-axis conductive lines 120. A plurality of interconnect conductive lines 130 may route the x-axis conductive lines 110 and the y-axis conductive lines 120 to a plurality of connector conductive lines 140. The plurality of connector conductive lines 140 may be configured to provide a connection to an interface (not shown) to a touch sensor controller (not shown) that detects touch through the touch sensor (not independently illustrated).

In certain embodiments, one or more of x-axis conductive lines 110, y-axis conductive lines 120, interconnect conductive lines 130, and connector conductive lines 140 may have different line widths and/or different orientations. The number of x-axis conductive lines 110, the line-to-line spacing between the x-axis conductive lines 110, the number of y-axis conductive lines 120, and the line-to-line spacing between the y-axis conductive lines 120 may vary based on an application. One of ordinary skill in the art will recognize that the size, configuration, and design of conductive pattern design 100 may vary in accordance with one or more embodiments of the present invention.

In certain embodiments, one or more of the x-axis conductive lines 110 and one or more of the y-axis conductive lines 120 may have a line width less than approximately 10 micrometers. In other embodiments, one or more of the x-axis conductive lines 110 and one or more of the y-axis conductive lines 120 may have a line width in a range between approximately 10 micrometers and approximately 50 micrometers. In still other embodiments, one or more of the x-axis conductive lines 110 and one or more of the y-axis conductive lines 120 may have a line width greater than approximately 50 micrometers. One of ordinary skill in the art will recognize that the shape and width of one or more of the x-axis conductive lines 110 and one or more of the y-axis conductive lines 120 may vary in accordance with one or more embodiments of the present invention.

In certain embodiments, one or more of the interconnect conductive lines 130 may have a line width in a range between approximately 50 micrometers and approximately 100 micrometers. One of ordinary skill in the art will recognize that the shape and width of one or more of the interconnect conductive lines 130 may vary in accordance with one or more embodiments of the present invention. In certain embodiments, one or more of the connector conductive lines 140 may have a line width greater than approximately 100 micrometers. One of ordinary skill in the art will recognize that the shape and width of one or more of the connector conductive lines 140 may vary in accordance with one or more embodiments of the present invention.

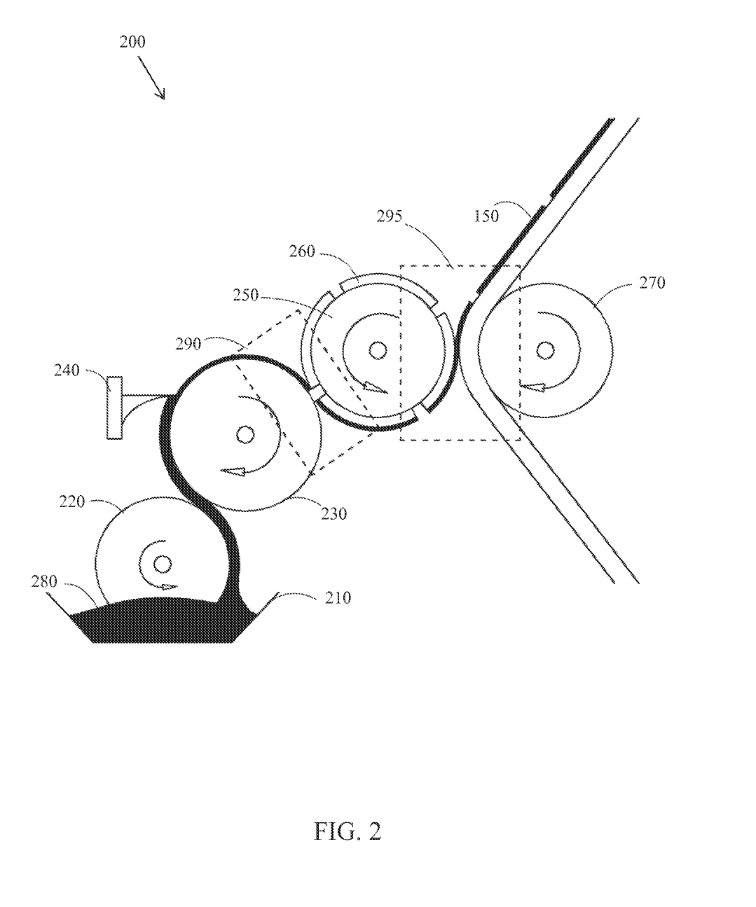

FIG. 2 shows a flexographic printing system 200 in accordance with one or more embodiments of the present invention. Flexographic printing system 200 may include an ink pan 210, an ink roll 220 (also referred to as a fountain roll), an anilox roll 230 (also referred to as a meter roll), a doctor blade 240, a printing plate cylinder 250, a flexographic printing plate 260, and an impression cylinder 270.

In operation, ink roll 220 transfers ink 280 from ink pan 210 to anilox roll 230. In certain embodiments, ink 280 may be a catalytic ink or catalytic alloy ink that serves as a plating seed suitable for metallization by electroless plating. In other embodiments, ink 280 may be an opaque ink or other opaque material suitable for flexographic printing. One of ordinary skill in the art will recognize that the composition of ink 280 may vary based on an application. Anilox roll 230 is typically constructed of a steel or aluminum core that may be coated by an industrial ceramic whose surface contains a plurality of very fine dimples, also referred to as cells (not shown). Doctor blade 240 removes excess ink 280 from anilox roll 230. In transfer area 290, anilox roll 230 meters the amount of ink 280 transferred to flexographic printing plate 260 to a uniform thickness. Printing plate cylinder 250 may be made of metal and the surface may be plated with chromium, or the like, to provide increased abrasion resistance. High-resolution flexographic printing plate 260 may be mounted to printing plate cylinder 250 by an adhesive (not shown).

One or more substrates 150 move between printing plate cylinder 250 and impression cylinder 270. In one or more embodiments of the present invention, substrate 150 may be transparent. Transparent means the transmission of visible light with a transmittance rate of 85% or more. In one or more embodiments of the present invention, substrate 150 may be polyethylene terephthalate (“PET”), polyethylene naphthalate (“PEN”), cellulose acetate (“TAC”), linear low-density polyethylene (“LLDPE”), bi-axially-oriented polypropylene (“BOPP”), polyester, polypropylene, or glass. One of ordinary skill in the art will recognize that the composition of substrate 150 may vary in accordance with one or more embodiments of the present invention. Impression cylinder 270 applies pressure to printing plate cylinder 250, transferring an image from the embossing patterns of flexographic printing plate 260 onto substrate 150 at transfer area 295. The rotational speed of printing plate cylinder 250 is synchronized to match the speed at which substrate 150 moves through flexographic printing system 200. The speed may vary between 20 feet per minute to 750 feet per minute.

In one or more embodiments of the present invention, flexographic printing system 200 may be used to print a precursor or catalyst ink of one or more conductive pattern designs (100 of FIG. 1) on one or more sides of substrate 150. In certain embodiments, subsequent to flexographic printing, the precursor or catalyst ink of the one or more conductive pattern designs (100 of FIG. 1) may be metallized by an electroless plating process, forming one or more conductive pattern designs (100 of FIG. 1) on substrate 150. In other embodiments, the ink may be a direct printed conductive ink that may not require electroless plating. The one or more conductive pattern designs (100 of FIG. 1) on substrate 150 may be used to form a projected capacitance touch sensor (not independently illustrated).

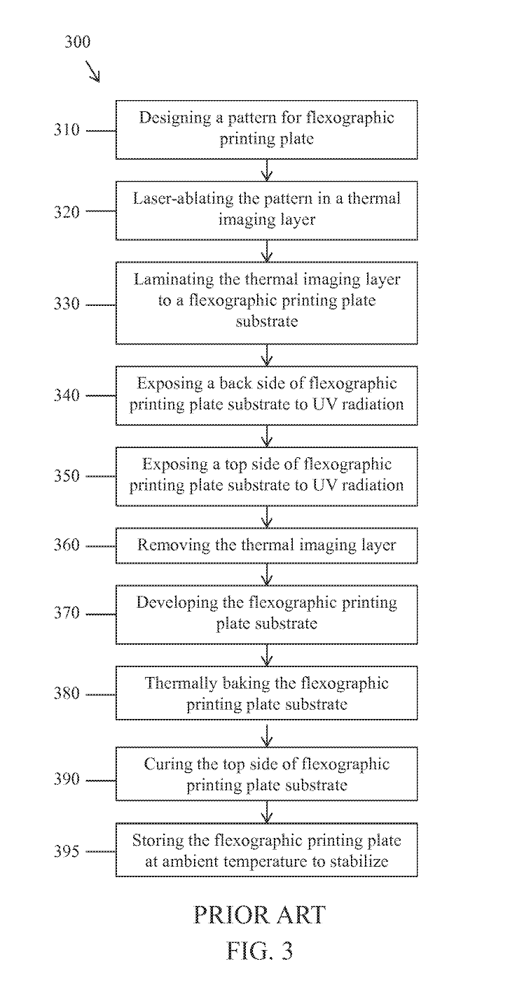

FIG. 3 shows a method of manufacturing a conventional flexographic printing plate. In step 310, a patterned design may be designed in a software application, such as a computer-aided drafting (“CAD”) software application. The patterned design includes an embossing pattern to be formed in a flexographic printing plate that, when used as part of a flexographic printing process, prints a corresponding patterned design on a substrate. In step 320, the patterned design is laser-ablated into a thermal imaging layer. The thermal imaging layer includes a PET base layer covered by a laser-ablation coating layer. The laser-ablation process ablates portions of the laser-ablation coating layer in a pattern corresponding to the patterned design, but the ablation does not extend into the PET base layer. After laser-ablation, the thermal imagining layer includes the PET base layer and remaining portions of the laser-ablation coating layer, where the exposed portions of the PET base layer correspond to the patterned design.

In step 330, the thermal imaging layer is laminated to a flexographic printing plate substrate. The flexographic printing plate substrate includes a PET base layer covered by a photopolymer layer. The thickness of the flexographic printing plate substrate may vary. For example, flexographic printing plate substrates are commonly produced with a thickness of 1.14 millimeters or 1.67 millimeters. The PET base layer of the flexographic printing plate substrate may have a thickness in a range between approximately 50 micrometers and 200 micrometers, with the remaining thickness attributed to the thickness of the photopolymer layer. The laser-ablation coating layer side of the thermal imaging layer is laminated to a top side, or photopolymer layer side, of the flexographic printing plate substrate.

In step 340, a bottom side of the flexographic printing plate substrate is exposed to ultraviolet (“UV”) radiation in an attempt to set a relief depth. The bottom side, or PET base layer side, of the flexographic printing plate is exposed to UV-A radiation, or another wavelength suitable for use with a given type of photopolymer material, for a period of time in a range between approximately 15 seconds and approximately 30 seconds, depending on the thickness of the flexographic printing plate substrate and the desired relief depth. However, the penetration of UV energy from the UV source side through the flexographic printing plate substrate is non-linear. The proprietary materials used by vendors of flexographic printing plate substrates may include additives such as photo-initiators and accelerants to promote or enhance the rate of the crosslinking process, but result in non-linearity. This non-linear depth of crosslinking results in a variable and typically wider window of relief depth that is not controlled. The relief depth may vary across the flexographic printing plate substrate. While this may not cause issues when printing standard geometry lines or features, it is problematic when printing high-resolution lines, features, or micro meshes. As a consequence, the exposure is not effective for setting a shallow relief depth for high-resolution applications.

In step 350, the top side of the flexographic printing plate substrate is exposed to

UV radiation to crosslink and polymerize the patterned design into the photopolymer layer. The top side of the flexographic printing plate substrate, through the thermal imaging layer, is exposed to UV-A radiation for a period of time in a range between approximately 5 minutes and approximately 30 minutes, depending on the thickness of the flexographic printing plate substrate and the desired relief depth. The conventional flexographic printing plate substrate materials are negatively photoactive when exposed to UV radiation. Thus, the exposed areas of the photopolymer layer remain on the PET base layer while the unexposed areas of the photopolymer layer are removed in the development step. In step 360, the thermal imaging layer is removed from the flexographic printing plate substrate.

In step 370, the flexographic printing plate substrate is developed. The flexographic printing plate substrate is developed with a washout liquid, such as a solvent or etchant, which removes the unexposed portions of the photopolymer layer and leaves the UV-exposed portions of the photopolymer layer in a pattern corresponding to the patterned design. In step 380, the flexographic printing plate substrate is thermally baked at a temperature in a range between approximately 50 degrees Celsius and approximately 60 degrees Celsius for a period of time in a range between approximately 1 hour and approximately 3 hours. In step 390, the flexographic printing plate is cured. The top side of the flexographic printing plate substrate is exposed to UV-A radiation for a period of time in a range between approximately 0.5 minutes and approximately 5 minutes and then exposed to UV-C radiation for a period of time in a range between approximately 5 minutes and approximately 25 minutes to control the ink wettability requirements. In step 395, the flexographic printing plate is stored for more than 8 hours at ambient temperatures to stabilize the plate, which is typically swollen from the solvent or etchant step of the manufacturing process.

The conventional flexographic printing plate is mounted to a printing plate cylinder for use in a flexographic printing process. However, the conventional flexographic printing plate is not suitable for printing high-resolution lines, features, or micro meshes. In common applications, such as color printing, a conventional flexographic printing plate has a relief depth, as measured from the top of the photopolymer layer down towards the PET base layer, in a range between 500 micrometers and 800 micrometers, nearly half of the total thickness of the photopolymer layer. As a consequence, the features formed in the conventional flexographic printing plate are softer, tacky, less rigid, and of less impact for conventional dot printing. However, this lack of rigidity of the features negatively affects the integrity of ink transfer during high-resolution flexographic printing operations. For example, a high-resolution image printed on a substrate by a conventional flexographic printing plate may exhibit waviness, smearing, and uneven ink distribution resulting in knots or bumps. These problems increase as the line or feature width of the patterned design decrease.

In one or more embodiments of the present invention, a method of manufacturing a flexographic printing plate for high-resolution printing controls the relief depth by a multi-step exposure process that provides strong and stable lines or features having micrometer-fine widths. The quality of an image printed by a flexographic printing plate in a flexographic printing system may be impacted by an aspect ratio of the line or feature width to the relief depth. As the desired line or feature width gets smaller, the relief depth must be reduced to maintain the aspect ratio. Thus, when printing high-resolution lines, features, or micro meshes with a line or feature width of 10 micrometers or less, the relief depth must be substantially shallower than that conventionally used. By reducing the relief depth, the base of the photopolymer layer is thicker and provides improved support and stability to the high-resolution embossing patterns of the flexographic printing plate. The improved support and stability reduces or eliminates waviness, smearing, and uneven ink distribution. In addition, the improved support and stability reduces flexographic printing plate distortion when mounted to a printing plate cylinder.

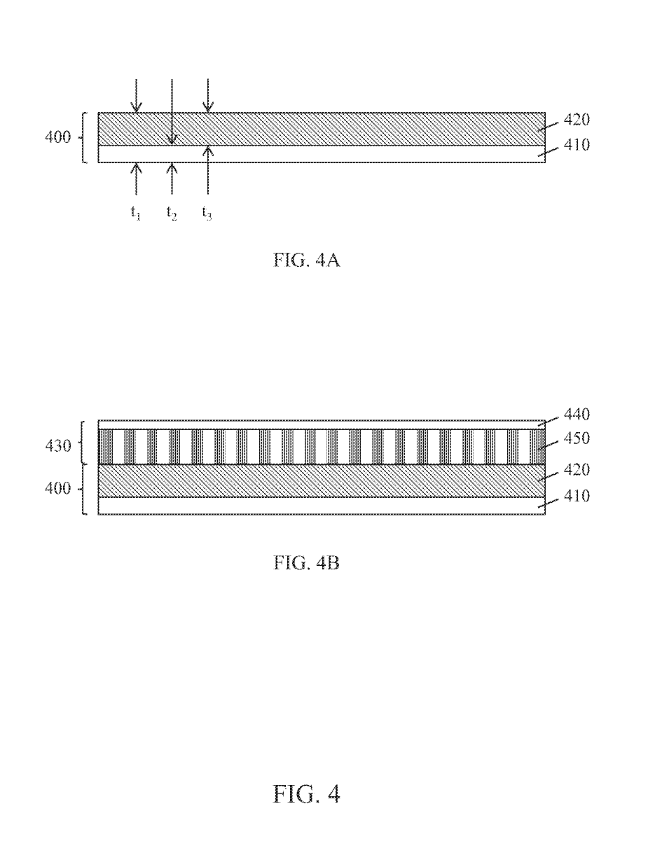

FIG. 4 shows a flexographic printing plate substrate at early stages of manufacture in accordance with one or more embodiments of the present invention. In FIG. 4A, a flexographic printing plate substrate 400 may be provided by a commercial vendor of flexographic printing plate substrates or custom manufactured for a specific design. Flexographic printing plate substrate 400 includes a base layer 410 that provides some manner of rigidity covered by a photopolymer layer 420 that is eventually patterned with a patterned design (not shown) such as, for example, a pattern corresponding to a high-resolution micro mesh (not shown) of a conductive pattern design (100 of FIG. 1). In certain embodiments, base layer 410 may be composed of a transparent and flexible PET material. In other embodiments, base layer 410 may be composed of PEN or other optically transparent and flexible film substrates. One of ordinary skill in the art will recognize that the composition of base layer 410 may vary in accordance with one or more embodiments of the present invention.

In certain embodiments, flexographic printing plate substrate 400 may have a length and a width suitable for mounting to an 18 inch printing plate cylinder. In other embodiments, flexographic printing plate substrate 400 may have a length and a width suitable for mounting to a 24 inch printing plate cylinder. One of ordinary skill in the art will recognize that the length and the width of flexographic printing plate substrate 400 may vary based on an application in accordance with one or more embodiments of the present invention.

In certain embodiments, flexographic printing plate substrate 400 may have a thickness, t₁, of approximately 1.14 millimeters. In other embodiments, flexographic printing plate substrate 400 may have a thickness, t₁, of approximately 1.67 millimeters. In still other embodiments, flexographic printing plate substrate 400 may have a custom thickness, t₁, corresponding to a specific design or application. One of ordinary skill in the art will recognize that the thickness, t₁, of flexographic printing plate substrate 400 may vary in accordance with the composition of substrate 400, a specific design, or application. In certain embodiments, base layer 410 may have a thickness, t₂, in a range between approximately 100 micrometers and approximately 200 micrometers. One of ordinary skill in the art will recognize that the thickness, t₂, of base layer 410 may vary based on the composition of base layer 410, a specific design, or application. The remaining thickness, t₃, of flexographic printing plate substrate 400 may be attributed to the thickness of photopolymer layer 420. The maximum possible relief depth (not shown) of the patterned design (not shown) that is eventually patterned into photopolymer layer 420 may be determined by the thickness, t₃, of photopolymer layer 420.

Continuing in FIG. 4B, thermal imaging layer 430 may be laminated to flexographic printing plate substrate 400. Thermal imaging layer 430 may be composed of a PET base layer 440 that provides some manner of rigidity covered by a laser-ablation coating layer 450 that may be patterned by a laser-ablation process. A patterned design (not shown) such as, for example, a pattern corresponding to a high-resolution micro mesh (not shown) of a conductive pattern design (100 of FIG. 1), may be laser-ablated into thermal imaging layer 430. As such, the exposed portions of PET base layer 440 of thermal imaging layer 430 correspond to the patterned design (not shown). The laser-ablation coating layer 450 side of thermal imaging layer 430 may be laminated to the photopolymer layer 420 side of flexographic printing plate substrate 400 using standard lamination processes.

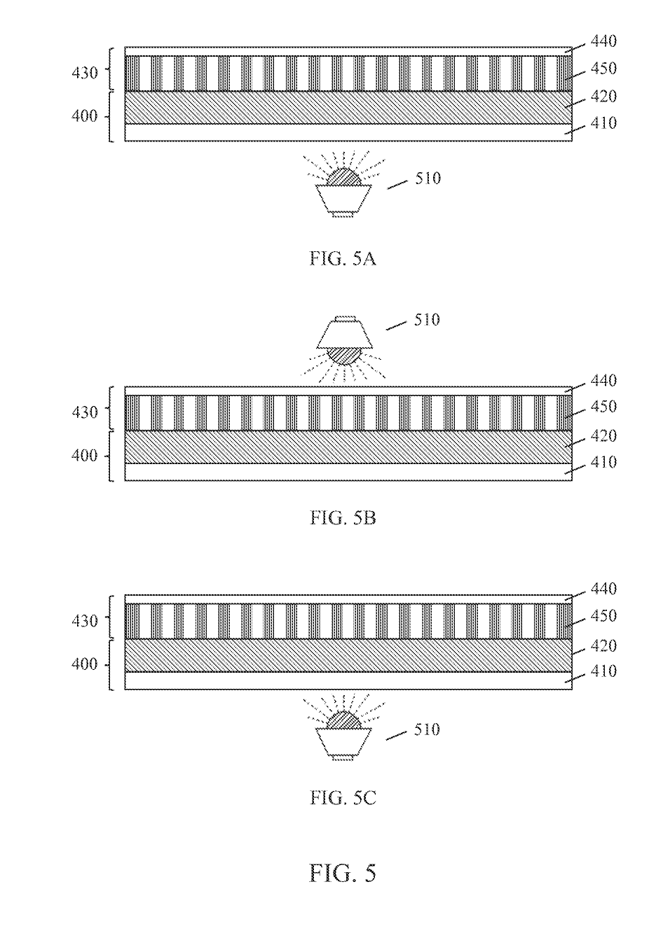

FIG. 5 shows a multi-step exposure of the flexographic printing plate substrate in accordance with one or more embodiments of the present invention. Continuing in FIG. 5A, a bottom side, or base layer 410 side, of flexographic printing plate substrate 400 may be exposed to UV-A radiation 510, or another wavelength suitable for use with a given type of photopolymer material, for a first time. The bottom side UV-A radiation 510 may partially polymerize a portion of photopolymer layer 420 from the bottom of photopolymer layer 420, nearest base layer 410, towards the top of photopolymer layer 420. The depth to which photopolymer layer 420 is polymerized may depend on the exposure time and the ability of UV-A radiation 510 to penetrate photopolymer layer 420. In one or more embodiments of the present invention, this first bottom side UV-A radiation 510 exposure time may be controlled so that a total bottom side UV-A radiation 510 exposure time sets a desired relief depth. The total exposure time estimated to achieve the desired relief depth may be partitioned between this first bottom side UV-A radiation 510 exposure time and a second bottom side UV-A radiation 510 exposure time shown in FIG. 5C.

In certain embodiments, the first bottom side UV-A radiation 510 exposure time as a percentage of the total bottom side UV-A radiation 510 exposure time may be approximately 50 percent. In other embodiments, the first bottom side UV-A radiation 510 exposure time as a percentage of the total bottom side UV-A radiation 510 exposure time may be in range between approximately 10 percent and approximately 90 percent. One of ordinary skill in the art will recognize that the first bottom side UV-A radiation 510 exposure time as a percentage of the total bottom side UV-A radiation 510 exposure time may vary in accordance with one or more embodiments of the present invention. In certain embodiments, the bottom side of flexographic printing plate substrate 400 may be first exposed to UV-A radiation 510 for a period of time in a range between approximately 10 seconds and approximately 20 seconds. In other embodiments, the bottom side of flexographic printing plate substrate 400 may be first exposed to UV-A radiation 510 for a period of time in a range between approximately 20 seconds and approximately 40 seconds. One of ordinary skill in the art will recognize that the first bottom side UV-A radiation 510 exposure time may vary in accordance with one or more embodiments of the present invention. In this way, this first bottom side UV-A radiation 510 exposure may establish an initial relief depth controlled by the duration of the exposure. As such, subsequent bottom side UV-A radiation exposure 510 may further decrease the relief depth in an additive manner to set the desired relief depth.

Continuing in FIG. 5B, a top side, or photopolymer layer 420 side, of flexographic printing plate substrate 400 may be exposed to UV-A radiation 510, or another wavelength suitable for use with a given type of photopolymer material, through thermal imaging layer 430 to form the desired patterned design in photopolymer layer 420. In certain embodiments, the top side of flexographic printing plate substrate 400 may be exposed to UV-A radiation 510 for a period of time in a range between approximately 200 seconds and approximately 1000 seconds. In other embodiments, the top side of flexographic printing plate substrate 400 may be exposed to UV-A radiation 510 for a period of time in a range between approximately 1000 seconds and approximately 2000 seconds. One of ordinary skill in the art will recognize that the top side UV-A radiation 510 exposure time may vary in accordance with one or more embodiments of the present invention.

Continuing in FIG. 5C, the bottom side of flexographic printing plate substrate 400 may be exposed to UV-A radiation 510, or another wavelength suitable for use with a given type of photopolymer material, for a second time. The bottom side UV-A radiation 430 may partially polymerize a portion of photopolymer layer 420. The depth to which photopolymer layer 420 is polymerized may depend on the exposure time and the ability of the UV-A radiation 510 to penetrate photopolymer layer 420. In one or more embodiments of the present invention, the second bottom side UV-A radiation 510 exposure time may be controlled so that the total bottom side UV-A radiation 510 exposure time sets the desired relief depth. The total exposure time estimated to achieve the desired relief depth may be partitioned between the first bottom side UV-A radiation 510 exposure time (FIG. 5A) and this second bottom side UV-A radiation 510 exposure time.

In certain embodiments, the second bottom side UV-A radiation 510 exposure time as a percentage of the total bottom side UV-A radiation 510 exposure time may be approximately 50 percent. In other embodiments, the second bottom side UV-A radiation 510 exposure time as a percentage of the total bottom side UV-A radiation 510 exposure time may be in range between approximately 90 percent and approximately 10 percent. One of ordinary skill in the art will recognize that the second bottom side UV-A radiation 510 exposure time as a percentage of the total bottom side UV-A radiation 510 exposure time may vary in accordance with one or more embodiments of the present invention. In certain embodiments, the bottom side of flexographic printing plate substrate 400 may be exposed to UV-A radiation 510 for a period of time in a range between approximately 10 seconds and approximately 20 seconds. In other embodiments, the bottom side of flexographic printing plate substrate 400 may be exposed to UV-A radiation 510 for a period of time in a range between approximately 20 seconds and approximately 40 seconds. One of ordinary skill in the art will recognize that the second bottom side UV-A radiation 510 exposure time may vary in accordance with one or more embodiments of the present invention. In certain embodiments, other combinations of multi-step exposure may be used to achieve repeatability and improved stability of patterns with a desired target relief depth. For example, in some cases, a bottom/top/bottom/top/bottom multi-step exposure process may be used.

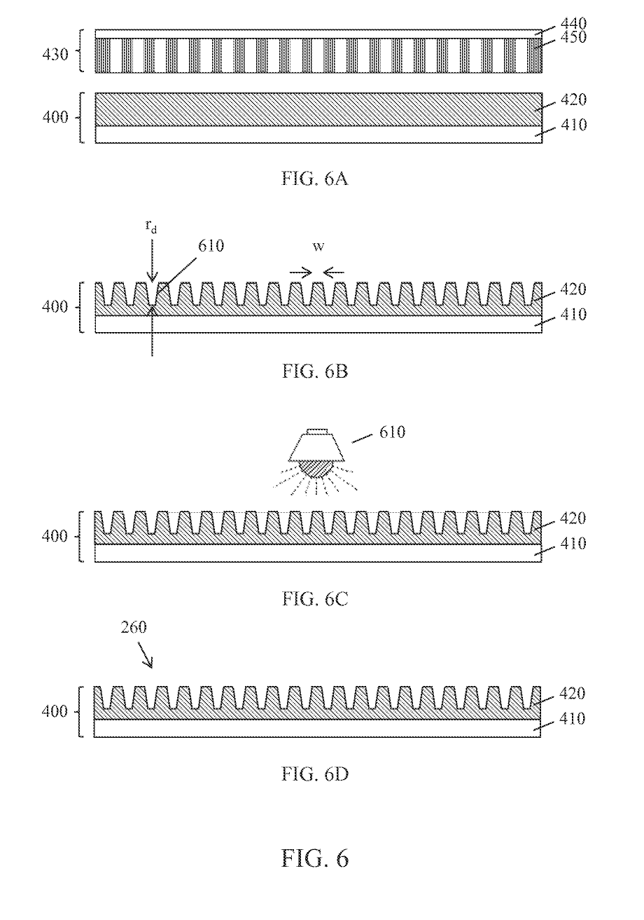

FIG. 6 shows post-exposure processing of the flexographic printing plate substrate in accordance with one or more embodiments of the present invention. Continuing in FIG. 6A, thermal imaging layer 430 may be removed from flexographic printing plate substrate 400 using standard delamination processes. Continuing in FIG. 6B, flexographic printing plate substrate 400 may be developed. Flexographic printing plate substrate 400 may be developed with a washout liquid, such as a solvent or etchant, which removes the unexposed portions of photopolymer layer 420 and leaves the UV-exposed portions of photopolymer layer 420 in a pattern corresponding to the patterned design (not shown).

The relief depth, r_{d}, may be measured from a top of photopolymer layer 420 and corresponds to the depth of the valleys 610 formed in photopolymer layer 420 between the remaining UV-exposed portions of photopolymer layer 420. The remaining UV-exposed portions of photopolymer layer 420 form the lines or features of the patterned design (not shown) and may have a width, w, of 10 micrometers or less. In certain embodiments, the relief depth, r_{d}, may be in a range between approximately 150 micrometers and approximately 300 micrometers. In other embodiments, the relief depth, r_{d}, may be in a range between approximately 20 micrometers and approximately 150 micrometers. In still other embodiments, the relief depth, r_{d}, may be in a range between approximately 300 micrometers and approximately 400 micrometers. One of ordinary skill in the art will recognize that the relief depth may vary based on a specific design or application.

The quality of an image (not shown) printed on substrate (150 of FIG. 1) may be determined by an aspect ratio of the line or feature width, w, to the relief depth, r_{d}, of the patterned flexographic printing plate (260 of FIG. 6D). As the desired line or feature width, w, of the flexographic printing plate (260 of FIG. 6D) gets smaller, the relief depth, r_{d}, must be reduced to maintain the aspect ratio. Thus, when printing high-resolution lines, features, or micro meshes with a line or feature width in a range between approximately 10 micrometers and approximately 1 micrometer, the relief depth, r_{d}, must be substantially shallower than that conventionally used. By reducing the relief depth, r_{d}, the base of photopolymer layer 420 may be thicker and provides improved support and stability to the patterned design (not shown) formed on the flexographic printing plate (260 of FIG. 6D). The improved support and stability reduces or eliminates waviness, smearing, and uneven ink distribution. The desired relief depth, r_{d}, may depend on the total bottom side exposure time.

After development, flexographic printing plate substrate 400 may be thermally baked (not shown) at a temperature in a range between approximately 50 degrees Celsius and approximately 60 degrees Celsius for a period of time in a range between approximately 1 hour and approximately 3 hours. Continuing in FIG. 6C, the top side of flexographic printing plate substrate 400 may be exposed to UV-A radiation for a period of time in a range between approximately 0.5 minutes and approximately 5 minutes to crosslink and strengthen the features, as needed. The top side of flexographic printing plate substrate 400 may then be exposed to UV-C radiation to remove any remaining volatile organic compounds and other contaminates from the surface of flexographic printing plate substrate 400, as needed. Flexographic printing plate substrate 400 may be stored for 8 or more hours at ambient temperatures to stabilize the plate, which is typically swollen from the solvent or etchant step of the manufacturing process. Continuing in FIG. 6D, flexographic printing plate 260 may be mounted to a printing plate cylinder (250 of FIG. 2) for use in a flexographic printing system (200 of FIG. 2).

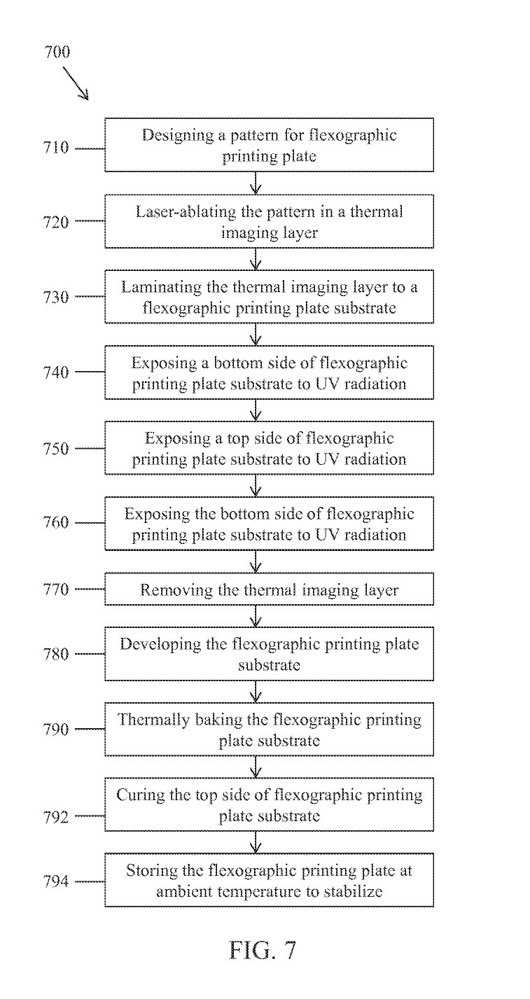

FIG. 7 shows a method 700 of manufacturing a high-resolution flexographic printing plate in accordance with one or more embodiments of the present invention. The method 700 may be used to manufacture a high-resolution flexographic printing plate (260 of FIGS. 2 and 6) for use in a flexographic printing system (200 of FIG. 2) configured to print a precursor or catalyst ink of a conductive pattern design (100 of FIG. 1) on a substrate (150 of FIG. 1).

In step 710, a patterned design may be designed in a software application, such as a CAD software application. The patterned design includes an embossing pattern eventually formed in a flexographic printing plate that, when used as part of a flexographic printing process, prints a corresponding patterned design on a substrate. The patterned design may correspond to a precursor or catalyst ink of a conductive pattern design that includes, for example, lines or features having a width of 10 micrometers of less.

In step 720, the patterned design may be laser-ablated into a thermal imaging layer. The thermal imaging layer includes a PET base layer covered by a laser-ablation coating layer. The laser-ablation process may ablate portions of the laser-ablation coating layer in a pattern corresponding to the patterned design, but does not extend into the PET base layer. After laser-ablation, the thermal imaging layer includes the PET base layer and remaining portions of the laser-ablation coating layer that is opaque. The exposed portions of the PET base layer of the thermal imaging layer correspond to the patterned design. In certain embodiments, the patterned design may be formed in a photomask that is used instead of the thermal imaging layer.

In step 730, the thermal imaging layer may be laminated to a flexographic printing plate substrate. The flexographic printing plate substrate may be provided by a commercial vendor of flexographic printing plate substrates or custom manufactured for a specific design. The flexographic printing plate substrate includes a base layer that provides some manner of rigidity covered by a photopolymer layer that is eventually patterned with the patterned design. In certain embodiments, the base layer may be composed of a transparent and flexible PET material. In other embodiments, the base layer may be composed of PEN or other optically transparent and flexible film substrates. One of ordinary skill in the art will recognize that the composition of the flexographic printing plate base layer may vary in accordance with one or more embodiments of the present invention.

In certain embodiments, the flexographic printing plate substrate may have a length and a width suitable for mounting to an 18 inch printing plate cylinder. In other embodiments, the flexographic printing plate substrate may have a length and a width suitable for mounting to a 24 inch printing plate cylinder. One of ordinary skill in the art will recognize that the length and the width of the flexographic printing plate substrate may vary based on an application in accordance with one or more embodiments of the present invention.

In certain embodiments, the flexographic printing plate substrate may have a thickness of approximately 1.14 millimeters. In other embodiments, the flexographic printing plate substrate may have a thickness of approximately 1.67 millimeters. In still other embodiments, the flexographic printing plate substrate may have a custom thickness corresponding to a specific design or application. One of ordinary skill in the art will recognize that the thickness of the flexographic printing plate substrate may vary in accordance with the composition of the flexographic printing plate substrate, a specific design, or application. In certain embodiments, the flexographic printing plate base layer may have a thickness in a range between approximately 100 micrometers and approximately 200 micrometers. One of ordinary skill in the art will recognize that the thickness of the flexographic printing plate base layer may vary based on the composition of the base layer, a specific design, or application. The remaining thickness of the flexographic printing plate substrate may be attributed to the thickness of the photopolymer layer. The maximum possible relief depth of the patterned design that is eventually patterned into the photopolymer layer may be determined by the thickness of the photopolymer layer. The laser-ablation coating layer side of the thermal imaging layer may be laminated to the photopolymer side of the flexographic printing plate substrate using standard lamination processes.

In step 740, a bottom side, or base layer side, of the flexographic printing plate substrate may be exposed to UV-A radiation, or another wavelength suitable for use with a given type of photopolymer material, for a first time. The bottom side UV-A radiation may polymerize a portion of the photopolymer layer from the bottom of the photopolymer layer, nearest the base layer, towards the top of the photopolymer layer. The depth to which the photopolymer layer is polymerized may depend on the exposure time and the ability of the UV-A radiation to penetrate the photopolymer layer. In one or more embodiments of the present invention, this first bottom side UV-A radiation exposure time may be controlled so that a total bottom side UV-A radiation exposure time sets a desired relief depth. The total exposure time estimated to achieve the desired relief depth may be partitioned between this first bottom side UV-A radiation exposure time and a second bottom side UV-A radiation exposure time.

In certain embodiments, the first bottom side UV-A radiation exposure time as a percentage of the total bottom side UV-A radiation exposure time may be approximately 50 percent. In other embodiments, the first bottom side UV-A radiation exposure time as a percentage of the total bottom side UV-A radiation exposure time may be in range between approximately 10 percent and approximately 90 percent. One of ordinary skill in the art will recognize that the first bottom side UV-A radiation exposure time as a percentage of the total bottom side UV-A radiation exposure time may vary in accordance with one or more embodiments of the present invention. In certain embodiments, the bottom side of the flexographic printing plate substrate may be first exposed to UV-A radiation for a period of time in a range between approximately 10 seconds and approximately 20 seconds. In other embodiments, the bottom side of the flexographic printing plate substrate may be first exposed to UV-A radiation for a period of time in a range between approximately 20 seconds and approximately 40 seconds. One of ordinary skill in the art will recognize that the first bottom side UV-A radiation exposure time may vary in accordance with one or more embodiments of the present invention.

In step 750, a top side, or photopolymer side, of the flexographic printing plate substrate may be exposed to UV-A radiation, or another wavelength suitable for use with a given type of photopolymer material, through the thermal imaging layer to form the desired patterned design in the photopolymer layer. In certain embodiments, the top side of the flexographic printing plate substrate may be exposed to UV-A radiation for a period of time in a range between approximately 200 seconds and approximately 1000 seconds. In other embodiments, the top side of the flexographic printing plate substrate may be exposed to UV-A radiation for a period of time in a range between approximately 1000 seconds and approximately 2000 seconds. One of ordinary skill in the art will recognize that the top side UV-A radiation exposure time may vary in accordance with one or more embodiments of the present invention.

In step 760, the bottom side of the flexographic printing plate substrate may be exposed to UV-A radiation, or another wavelength suitable for use with a given type of photopolymer material, for a second time. The bottom side UV-A radiation may partially polymerize a portion of the photopolymer layer. The depth to which the photopolymer layer is polymerized may depend on the exposure time and the ability of the UV-A radiation to penetrate the photopolymer layer. In one or more embodiments of the present invention, the second bottom side UV-A radiation exposure time may be controlled so that the total bottom side UV-A radiation exposure time sets the desired relief depth. The total exposure time estimated to achieve the maximum desired depth may be partitioned between the first bottom side UV-A radiation exposure time of step 740 and this second bottom side UV-A radiation exposure time of step 760.

In certain embodiments, the second bottom side UV-A radiation exposure time as a percentage of the total bottom side UV-A radiation exposure time may be approximately 50 percent. In other embodiments, the second bottom side UV-A radiation exposure time as a percentage of the total bottom side UV-A radiation exposure time may be in range between approximately 90 percent and approximately 10 percent. One of ordinary skill in the art will recognize that the second bottom side UV-A radiation exposure time as a percentage of the total bottom side UV-A radiation exposure time may vary in accordance with one or more embodiments of the present invention. In certain embodiments, the bottom side of the flexographic printing plate substrate may be exposed to UV-A radiation for a period of time in a range between approximately 10 seconds and approximately 20 seconds. In other embodiments, the bottom side of the flexographic printing plate substrate may be exposed to UV-A radiation for a period of time in a range between approximately 20 second and approximately 40 seconds. One of ordinary skill in the art will recognize that the second bottom side UV-A radiation exposure time may vary in accordance with one or more embodiments of the present invention.

In step 770, the thermal imaging layer may be removed from the flexographic printing plate substrate using standard delamination processes. In step 780, the flexographic printing plate may be developed. The flexographic printing plate substrate may be developed with a washout liquid, such as a solvent or etchant, which removes the unexposed portions of the photopolymer layer and leaves the UV-exposed portions of the photopolymer layer in a pattern corresponding to the patterned design.

The relief depth may be measured from a top of the photopolymer layer and corresponds to the depth of the valleys formed in the photopolymer layer between the remaining UV-exposed portions of the photopolymer layer. The remaining UV-exposed portions of the photopolymer layer form the lines or features of the patterned design and may have a width of 10 micrometers or less. In certain embodiments, the relief depth may be in a range between approximately 150 micrometers and approximately 300 micrometers. In other embodiments, the relief depth may be in a range between approximately 20 micrometers and approximately 150 micrometers. In still other embodiments, the relief depth may be in a range between approximately 300 micrometers and approximately 400 micrometers. One of ordinary skill in the art will recognize that the relief depth may vary based on a specific design or application.

The quality of a printed image on a substrate by a flexographic printing system may be impacted by an aspect ratio of the line or feature width to the relief depth of the patterned flexographic printing plate. As the desired line or feature width of the flexographic printing plate gets smaller, the relief depth must be reduced to maintain the aspect ratio. Thus, when printing high-resolution lines, features, or micro meshes with a line or feature width in a range between approximately 10 micrometers and approximately 1 micrometer, the relief depth must be substantially shallower than that conventionally used. By reducing the relief depth, the base of the photopolymer layer may be thicker and provides improved support and stability to the patterned design formed on the flexographic printing plate. The improved support and stability reduces or eliminates waviness, smearing, and uneven ink distribution.

In step 790, the flexographic printing plate substrate may be thermally baked to restore some rigidity to it after the development process. The flexographic printing plate substrate may be thermally baked at a temperature in a range between approximately 50 degrees Celsius and approximately 60 degrees Celsius for a period of time in a range between approximately 1 hour and approximately 3 hours. In step 792, the flexographic printing plate substrate may be cured. The top side of the flexographic printing plate substrate may be exposed to UV-A radiation for a period of time in a range between approximately 0.5 minutes and approximately 5 minutes to crosslink or strengthen the features, as needed. The top side of the flexographic printing plate may then be exposed to UV-C radiation to remove any remaining volatile organic compounds and other contaminates from the surface of the flexographic printing plate, as needed. In step 794, the flexographic printing plate substrate may be stored. The flexographic printing plate substrate may be stored for 8 or more hours at ambient temperatures to stabilize the plate, which is typically swollen from the solvent or etchant step of the manufacturing process. One of ordinary skill in the art will recognize that the storage time may vary in accordance with one or more embodiments of the present invention. After manufacturing, the flexographic printing plate may be mounted to a printing plate cylinder for use in a flexographic printing system.

Advantages of one or more embodiments of the present invention may include one or more of the following:

In one or more embodiments of the present invention, a method of manufacturing a flexographic printing plate controls the relief depth by a multi-step exposure process.

In one or more embodiments of the present invention, a method of manufacturing a flexographic printing plate compensates for the non-linear penetration of UV radiation into the photopolymer layer of the flexographic printing plate substrate.

In one or more embodiments of the present invention, a method of manufacturing a flexographic printing plate provides a shallow relief depth that provides a thicker base of polymerized photopolymer material that provides increased support and stability.

In one or more embodiments of the present invention, a method of manufacturing a flexographic printing plate provides a shallow relief depth suitable for use with micrometer-fine lines or features.

In one or more embodiments of the present invention, a method of manufacturing a flexographic printing plate maintains a desirable aspect ratio for micrometer-fine line or feature width to relief depth.

In one or more embodiments of the present invention, a method of manufacturing a flexographic printing plate may scale to smaller lines or features with shallower relief depths while maintaining a desirable aspect ratio.

In one or more embodiments of the present invention, a method of manufacturing a flexographic printing plate reduces the variability in relief depth from line to line.

In one or more embodiments of the present invention, a method of manufacturing a flexographic printing plate reduces or eliminates waviness, smearing, or uneven ink distribution during flexographic printing operations.

In one or more embodiments of the present invention, a method of manufacturing a flexographic printing plate may produce a flexographic printing plate capable of printing high-resolution lines or features having a width of 1 micrometer of less.

In one or more embodiments of the present invention, a method of manufacturing a flexographic printing plate may produce a flexographic printing plate capable of printing high-resolution lines or features having a width of 5 micrometers of less.

In one or more embodiments of the present invention, a method of manufacturing a flexographic printing plate may produce a flexographic printing plate capable of printing high-resolution lines or features having a width of 10 micrometers of less.

In one or more embodiments of the present invention, a method of manufacturing a flexographic printing plate may produce a flexographic printing plate capable of printing high-resolution lines or features that are smaller than a conventional flexographic printing plate is capable of printing.

In one or more embodiments of the present invention, a method of manufacturing a flexographic printing plate may produce a flexographic printing plate capable of printing high-resolution micro meshes that are smaller than a conventional flexographic printing plate is capable of printing.

In one or more embodiments of the present invention, a method of manufacturing a flexographic printing plate may produce a flexographic printing plate with a shallower relief depth than a conventional flexographic printing plate.

In one or more embodiments of the present invention, a method of manufacturing a flexographic printing plate may produce a flexographic printing plate that is stronger and more stable than a conventional flexographic printing plate.

In one or more embodiments of the present invention, a method of manufacturing a flexographic printing plate produces a flexographic printing plate compatible with flexographic printing processes.

While the present invention has been described with respect to the above-noted embodiments, those skilled in the art, having the benefit of this disclosure, will recognize that other embodiments may be devised that are within the scope of the invention as disclosed herein. Accordingly, the scope of the invention should be limited only by the appended claims.

What is claimed is:

1. A method of manufacturing a flexographic printing plate comprising:
exposing a bottom side of a flexographic printing plate substrate to UV-A radiation for a first exposure time;
exposing a top side of the flexographic printing plate substrate to UV-A radiation through a thermal imaging layer;
exposing the bottom side of the flexographic printing plate substrate to UV-A radiation for a second exposure time;
developing the flexographic printing plate substrate; and
curing the flexographic printing plate substrate,
wherein a sum of the first and second exposure times set a relief depth.

2. The method of claim 1, wherein the first exposure time is 50 percent of the sum of the first and second exposure times.

3. The method of claim 2, wherein the second exposure time is 50 percent of the sum of the first and second exposure times.

4. The method of claim 1, wherein the first exposure time is in a range between approximately 10 percent and approximately 90 percent of the sum of the first and second exposure times.

5. The method of claim 4, wherein the second exposure time is in a range between approximately 90 percent and approximately 10 percent of the sum of the first and second exposure times.

6. The method of claim 1, wherein the first exposure time is in a range between approximately 10 seconds and approximately 20 seconds.

7. The method of claim 1, wherein the second exposure time is in a range between approximately 10 seconds and approximately 20 seconds.

8. The method of claim 1, wherein the top side of the flexographic printing plate is exposed to UV-A radiation for a period of time in a range between approximately 200 seconds and approximately 1000 seconds.

9. The method of claim 1, wherein the flexographic printing plate comprises one or more lines having a width of 10 micrometers or less.

10. The method of claim 1, wherein the relief depth is in a range between approximately 150 micrometers and approximately 300 micrometers.

11. The method of claim 1, wherein the relief depth is in a range between approximately 20 micrometers and approximately 150 micrometers.

12. The method of claim 1, wherein the relief depth is in a range between approximately 300 micrometers and approximately 400 micrometers.

13. The method of claim 1, further comprising:
designing a patterned design;
laser-ablating the patterned design into the thermal imaging layer; and
laminating the thermal imaging layer to the flexographic printing plate substrate.

14. The method of claim 13, wherein the patterned design comprises a micro mesh, the micro mesh comprising one or more lines having a width of 10 micrometers or less.

15. The method of claim 1, further comprising:
thermally baking the flexographic printing plate substrate at a temperature in a range between approximately 50 degrees Celsius and approximately 60 degrees Celsius for a period of time in a range between approximately 1 hour and approximately 3 hours.

16. The method of claim 1, further comprising:
storing the flexographic printing plate substrate at an ambient temperature.

17. The method of claim 1, wherein the flexographic printing plate substrate comprises a PET base layer and a photopolymer layer.

18. The method of claim 1, wherein the thermal imaging layer comprises a PET base layer and a laser-ablation coating layer.

19. The method of claim 1, wherein developing comprises removing unexposed portions of a photopolymer layer with a washout liquid.

20. The method of claim 1, wherein curing comprises exposing the top side of the flexographic printing plate substrate to UV-A radiation followed by exposure to UV-C radiation.
